(19) United States
(12) Patent Application Publication
(10) Pub. No.: US 2019/0080821 A1
(43) Pub. Date: Mar. 14, 2019

(54) SHIELDED CONDUCTIVE PATH AND RELAY CONNECTING MEMBER

(71) Applicant: SUMITOMO WIRING SYSTEMS, LTD., Yokkaichi-shi (JP)

(72) Inventor: Naoto TSUKIMORI, Yokkaichi (JP)

(73) Assignee: SUMITOMO WIRING SYSTEMS, LTD., Yokkaichi-shi (JP)

(21) Appl. No.: 16/037,627

(22) Filed: Jul. 17, 2018

(30) Foreign Application Priority Data
Sep. 13, 2017 (JP) 2017-175630

(51) Int. Cl. H01B 7/00; H01B 7/17; H01R 4/64; H02G 3/04; H02G 3/06; H05K 9/00

(52) U.S. Cl. CPC H01B 7/0081; H01B 7/17; H05K 9/0098; H02G 3/0406; H02G 3/06; H01R 4/64

(57) ABSTRACT

Provided is a shielded conductive path that can be adapted to a branch structure without making the shape of a shielding member more complex. A shielded conductive path includes a trunk line electric wire, branch line electric wires connected to the trunk line electric wire via branching portions, trunk line shielding members having conductivity and enclosing the outer circumference of the trunk line electric wire, and branch line shielding members having conductivity and enclosing the outer circumference of the branch line electric wires. Moreover, the shielded conductive path includes a relay connecting member having conductivity, the relay connecting member being disposed corresponding to the branching portions, and the trunk line shielding members and the branch line shielding members being attached to and in contact with the relay connecting member.

### TECHNICAL FIELD

The present disclosure relates to a shielded conductive path and a relay connecting member.

### BACKGROUND ART

A shielded conductive path disclosed in JP 2012-84275A includes a bundle of electric wires installed between devices, a shielding member that covers the bundle of electric wires, and a shielding shell made of metal and conductively connected to the shielding member. The shielding member is configured to suppress the generation of electromagnetic noise by covering the bundle of electric wires. This shielding member is a tubular, braided member and has a single trunk passage that has an inlet hole and two branch passages into which the trunk passage bifurcates and which each have an outlet hole.

The bundle of electric wires passing through the trunk passage branches into two bundles, which are inserted into the two respective branch passages. An open end portion on the inlet side of the trunk passage and open end portions on the outlet side of the two branch passages are connected to respectively corresponding shielding shells. Moreover, each shielding shell is connected to a shielding case on a device side.

JP 2012-84275A is an example of related art.

In the above-described case, when the branch structure of the shielded conductive path is complex, the shape of the shielding member also becomes complex. However, since the shielding member is a braided member formed by braiding thin metal wires in the manner of a mesh, it is difficult to adapt the shielding member to a complex branch structure, and there is a risk that the shielding member will be difficult to manufacture.

### SUMMARY

The present disclosure was made based on such circumstances as described above, and it is an object thereof to provide a shielded conductive path that can be adapted to a branch structure without making the shape of a shielding member more complex.

A shielded conductive path according to the present invention includes a trunk line electric wire, a branch line electric wire connected to the trunk line electric wire via a branching portion, a trunk line shielding member having conductivity and enclosing an outer circumference of the trunk line electric wire, a branch line shielding member having conductivity and enclosing an outer circumference of the branch line electric wire, and a relay connecting member having conductivity and disposed corresponding to the branching portion, the trunk line shielding member and the branch line shielding member being attached to and in contact with the relay connecting member.

Since the trunk line shielding member and the branch line shielding member are attached to and in contact with the relay connecting member that is disposed corresponding to the branching portion, the shielded conductive path can be adapted to the branch structure of the branching portion via the relay connecting member without making the shapes of the trunk line shielding member and the branch line shielding members more complex.

### BRIEF DESCRIPTION OF THE DRAWINGS

FIG. 1 is a perspective view of a shielded conductive path according to Embodiment 1;

FIG. 2 is a front view of the shielded conductive path;

FIG. 3 is an enlarged view showing a connection structure between a relay connecting member and a trunk line shielding member;

FIG. 4 is a perspective view of the relay connecting member;

FIG. 5 is a front view of the relay connecting member;

FIG. 6 is a perspective view of a divided member;

FIG. 7 is a plan view of the divided member;

FIG. 8 is a front view of the divided member;

FIG. 9 is a perspective view showing a state in which the relay connecting member is disposed corresponding to branching portions, and trunk line electric wires and branch line electric wires extend in mutually intersecting directions;

FIG. 10 is a perspective view of a relay connecting member according to Embodiment 2;

FIG. 11 is a front view of the relay connecting member according to Embodiment 2;

FIG. 12 is a perspective view of a divided member according to Embodiment 2;

FIG. 13 is a plan view of the divided member according to Embodiment 2;

FIG. 14 is a front view of the divided member according to Embodiment 2; and

FIG. 15 is a diagram showing Embodiment 2 and corresponding to FIG. 9.

### EMBODIMENTS

Preferred embodiments will be described below.

It is preferable that the relay connecting member has a trunk line tube portion in which the trunk line electric wire can be inserted and a branch line tube portion in which the branch line electric wire can be inserted, the trunk line shielding member is attached to an outer circumferential surface of the trunk line tube portion, and the branch line shielding member is attached to an outer circumferential surface of the branch line tube portion. With this configuration, the relay connecting member can have the function of protecting the trunk line electric wire and the branch line electric wire in addition to the shielding function. Moreover, the trunk line shielding member and the branch line shielding member can be easily attached to the trunk line tube portion and the branch line tube portion, respectively.

It is preferable that the branch line tube portion and the trunk line tube portion have an integrated shape in which the branch line tube portion and the trunk line tube portion intersect and are connected to each other at the branching portion. With this configuration, the relay connecting member can have the function of defining the branching angle of the branching portion in addition to the shielding function. Moreover, the trunk line shielding member and the branch line shielding member can be connected to a single relay connecting member together, and thus, an increase in the number of components can be prevented.

It is preferable that the relay connecting member is constituted by a pair of divided members that can be separated from each other and put together with the trunk line electric wire and the branch line electric wire held between the divided members. With this configuration, after the branching portion has been formed, the trunk line electric wire and the branch line electric wire are installed in one divided member of the two divided members so as to extend along the divided member, and in this state, this divided member and the other divided member are put together. In this manner, a relay connecting member in which the trunk line electric wire and the branch line electric wire are inserted can be formed.

### Embodiment 1

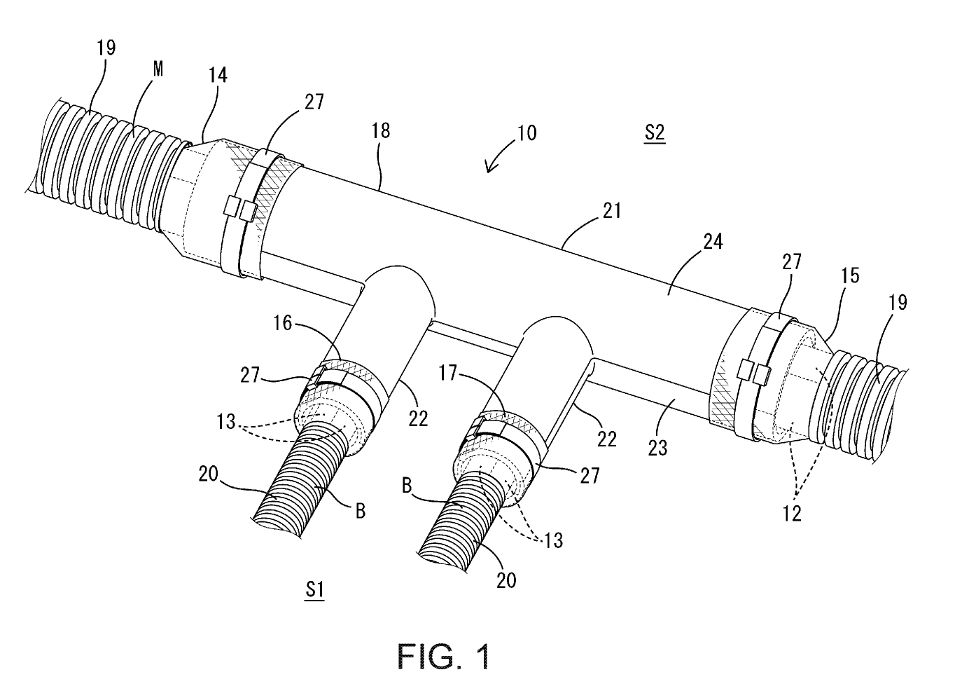

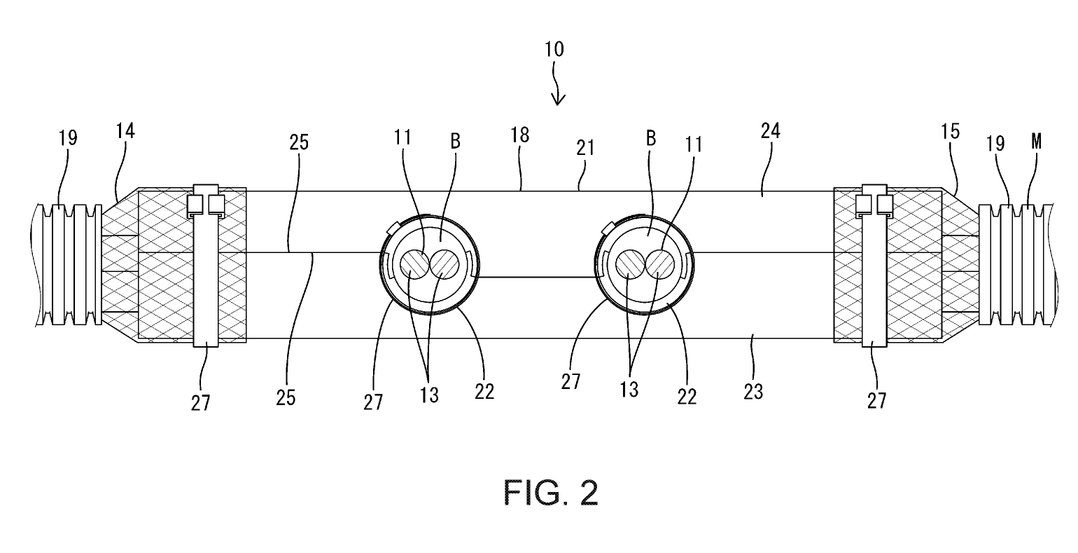

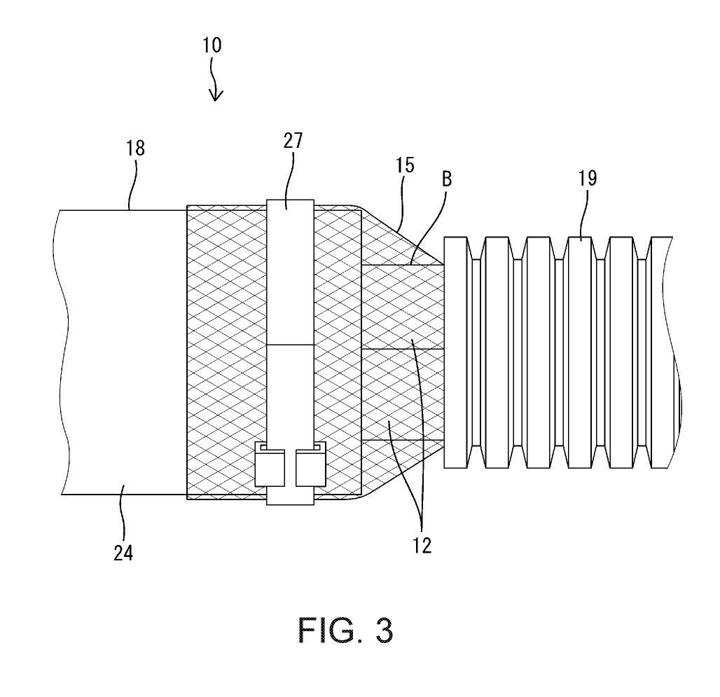

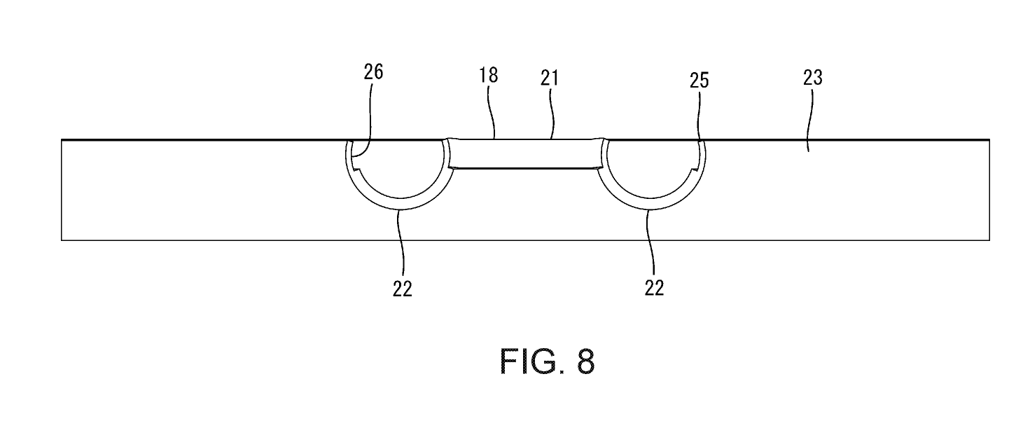

Hereinafter, Embodiment 1 will be described based on FIGS. 1 to 9. A shielded conductive path 10 according to Embodiment 1 is installed in a vehicle such as an automobile, and in order to meet an optional specification adapted to user needs, branch lines B for an optional device branch off from a trunk line M via branching portions 11. As shown in FIGS. 1 and 2, the shielded conductive path 10 includes a plurality of trunk line electric wires 12 constituting the trunk line M, a plurality of branch line electric wires 13 constituting the branch lines B, a plurality of trunk line shielding members 14 and 15 that collectively enclose the outer circumference of the trunk line electric wires 12 on opposite sides of the branching portions 11 in the length direction, a plurality of branch line shielding members 16 and 17 that collectively enclose the outer circumference of the branch line electric wires 13 of the respective branch lines B, and a single relay connecting member 18 to which the trunk line shielding members 14 and 15 and the branch line shielding members 16 and 17 are connected.

The branch line electric wires 13 and the trunk line electric wires 12 are each configured as an unshielded electric wire in which the circumference of a core wire portion is enclosed by an insulating resin. A plurality of (two, in the case shown in the drawings) branch line electric wires of the branch line electric wires 13 make a set and are connected to a single trunk line electric wire 12 that is for splicing, thereby constituting a branch line B.

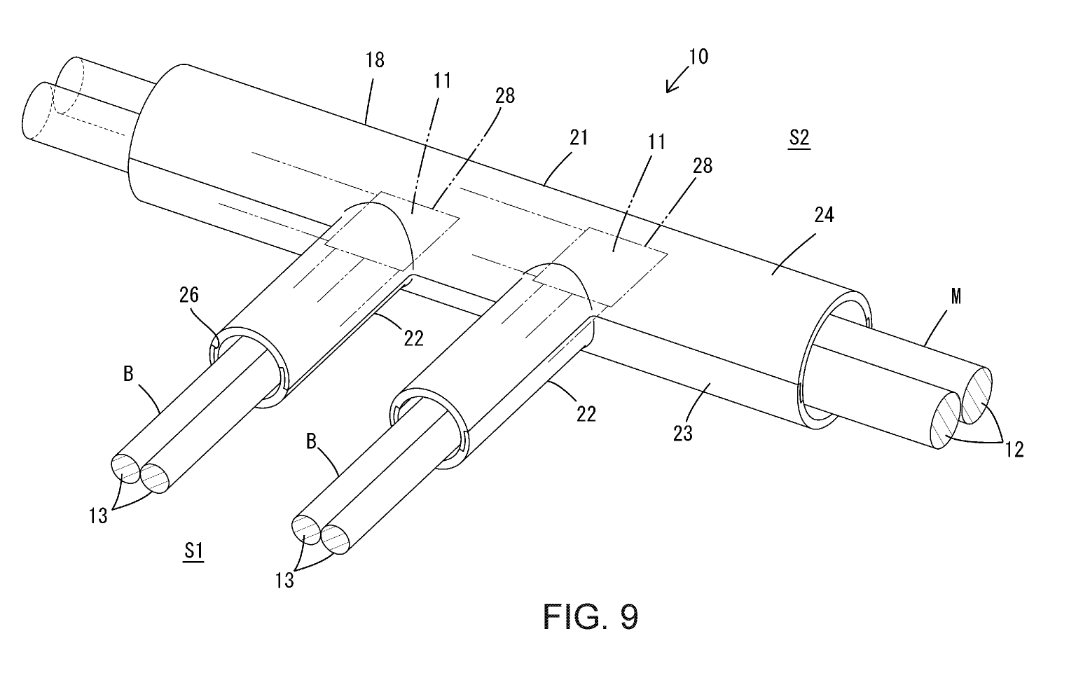

At each branching portion 11, the branch line electric wires 13 (more specifically, a set of branch line electric wires 13) are electrically and mechanically connected to the trunk line electric wire 12 for a corresponding one of the branch lines B, of the trunk line electric wires 12, via a splice terminal 28 (see FIG. 9, although a specific structure thereof is not shown). As shown in FIG. 9, the branch line electric wires 13 are connected to the corresponding trunk line electric wires 12 at the two branching portions 11 spaced apart from each other in the length direction of the trunk line M (trunk line electric wires 12) such that the branch line electric wires 13 intersect (more specifically, orthogonally intersect) the length direction of the trunk line M and extend from the trunk line M substantially parallel to each other toward a space S1 on one side, of spaces S1 and S2 on opposite sides of the trunk line M.

Opposite end portions of each trunk line electric wire 12 in the length direction are connected to respectively corresponding standard devices via connectors, which are not shown. Similarly, end portions of the branch line electric wires 13 in the length direction, of each branch line B are connected to a corresponding optional device via a connector, which is not shown.

As shown in FIGS. 1 to 3, all of the trunk line shielding members 14 and 15 and the branch line shielding members 16 and 17 are braided members having pliability and stretchability, and are formed in a tubular shape by braiding thin metal wires made of copper, aluminum, or the like in the manner of a mesh. The trunk line shielding members 14 and 15 and the branch line shielding members 16 and 17 extend substantially straight in one direction and have a common shape that is the same as those of existing shielding members.

As shown in FIG. 1, the trunk line shielding members 14 and 15 include the trunk line shielding member 14 that is disposed on a first side in the length direction, of opposite sides of the branching portions 11 (portions corresponding to which the relay connecting member 18 is located) in the length direction, and the trunk line shielding member 15 that is disposed on a second side in the length direction, of opposite sides. These trunk line shielding members 14 and 15 have substantially the same opening diameter. The branch line shielding members 16 and 17 are provided for the respective branch lines B, and both have a smaller opening diameter than the trunk line shielding members 14 and 15.

The outer circumference of the trunk line shielding members 14 and 15 and the outer circumference of the branch line shielding members 16 and 17 are enclosed and protected by corrugated tubes 19 and 20. As shown in FIG. 1, the corrugated tubes 19 and 20 are in the form of a bendable bellows tube made of a synthetic resin, and have a shape in which ridges and grooves alternate in the length direction. The corrugated tubes 19 that cover the trunk line shielding members 14 and 15 are slightly larger than the corrugated tubes 20 that cover the branch line shielding members 16 and 17.

The relay connecting member 18 is made of a metal such as iron, aluminum, copper, or the like, and is preferably composed of the same material (e.g., aluminum) as the trunk line shielding members 14 and 15 and the branch line shielding members 16 and 17.

As shown in FIG. 1, the relay connecting member 18 is constituted by a cylindrical tubular, trunk line tube portion 21 in which intermediate portions of the trunk line electric wires 12 in the length direction are inserted and cylindrical tubular, branch line tube portions 22 in each of which portions of the branch line electric wires 13, the portions being located near the branching portions 11, of a corresponding one of the branch lines B are inserted. The trunk line tube portion 21 extends in the length direction of the trunk line M and defines an installation direction of the trunk line M. Similarly, the branch line tube portions 22 extend in the length direction of the respective branch lines B and define installation directions of the respective branch lines B.

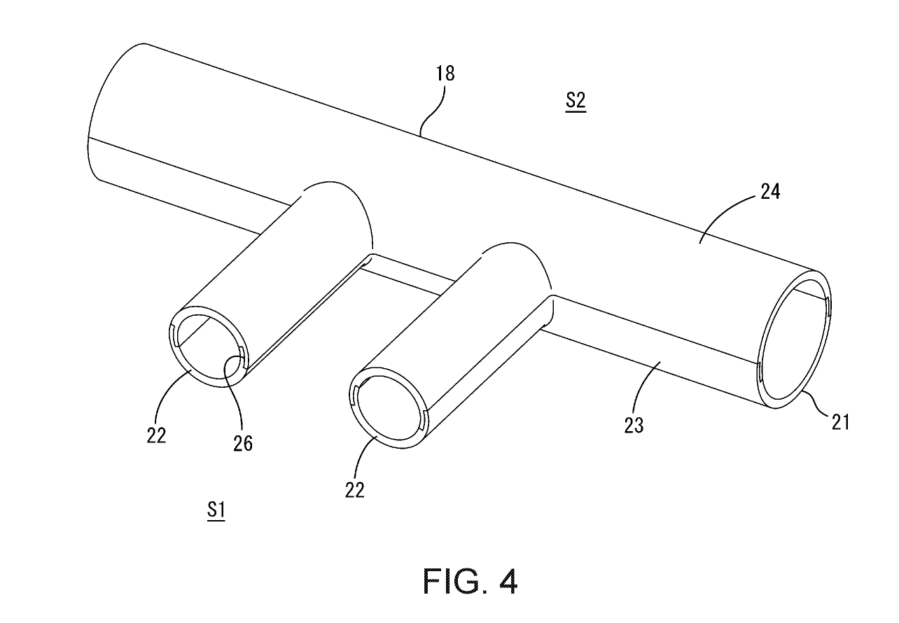

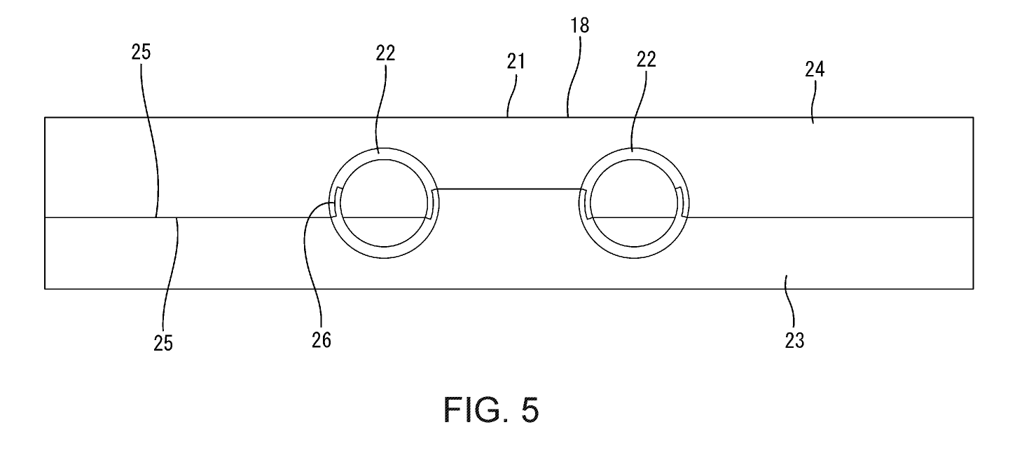

As shown in FIGS. 4 and 5, the branch line tube portions 22 are integrally connected to two respective portions of the trunk line tube portion 21 that are spaced apart from each other in the length direction of the trunk line tube portion 21, while intersecting (more specifically, orthogonally intersecting) the trunk line tube portion 21, and are provided as a pair so as to protrude substantially parallel to each other from the trunk line tube portion 21 toward the space S1 on one side, of the spaces S1 and S2 on opposite sides of the trunk line tube portion 21. Thus, the relay connecting member 18 is formed in a substantially Π (pi) shape as a whole. Note that each branch line tube portion 22 is slightly smaller than the trunk line tube portion 21.

As shown in FIG. 9, the relay connecting member 18 is externally fitted onto the trunk line electric wires 12 and the branch line electric wires 13 so as to cover the two branching portions 11. Portions of each trunk line electric wire 12 on opposite sides in the length direction are drawn out in opposite directions from opposite end portions of the trunk line tube portion 21 in the length direction thereof. On the other hand, the branch line electric wires 13 of each branch line B are drawn out from an end portion (extending end portion) of a corresponding one of the branch line tube portions 22 in the length direction thereof. Thus, branching angles that the respective branch lines B form with the trunk line M at the branching portions 11 are defined by the relay connecting member 18.

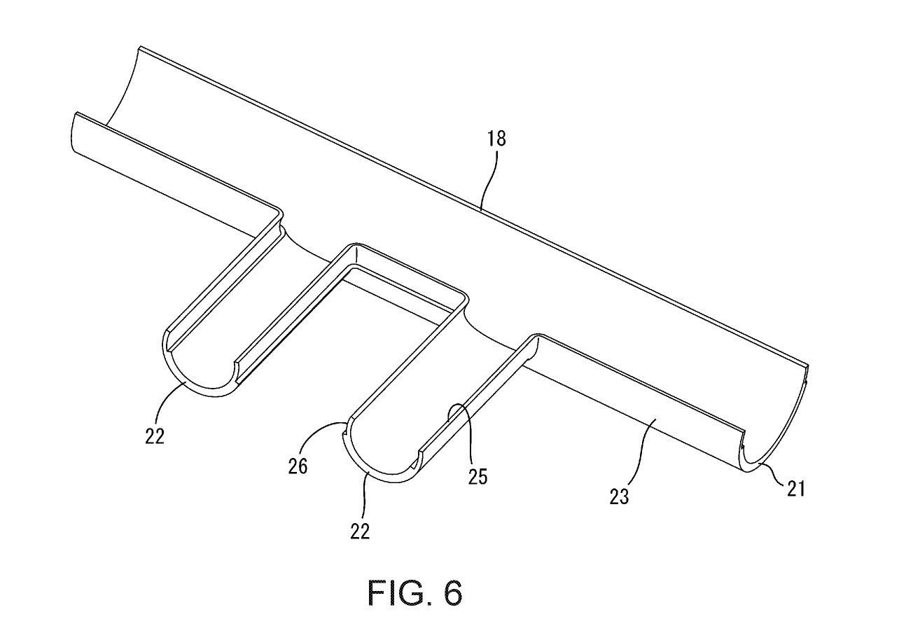

Moreover, the relay connecting member 18 is constituted by a pair of divided members 23 and 24 formed by dividing the trunk line tube portion 21 and the branch line tube portions 22 into two parts in the radial direction so that the divided members 23 and 24 can be separated from each other and put together in the radial direction with the trunk line electric wires 12 and the branch line electric wires 13 held between the divided members 23 and 24. As shown in FIGS. 6 to 8, the two divided members 23 and 24 are each formed in a trough-like shape having a substantially semi-circular arc-shaped cross section and extending in the length directions of the trunk line M and the branch lines B. When the two divided members 23 and 24 are put together with divided surfaces 25 of one of the divided members abutting against corresponding divided surfaces 25 of the other one of the divided members, the dividing surfaces 25 being provided at both ends of the divided members in the circumferential direction, the trunk line tube portion 21 and the branch line tube portions 22 that each have a substantially circular cross section are formed.

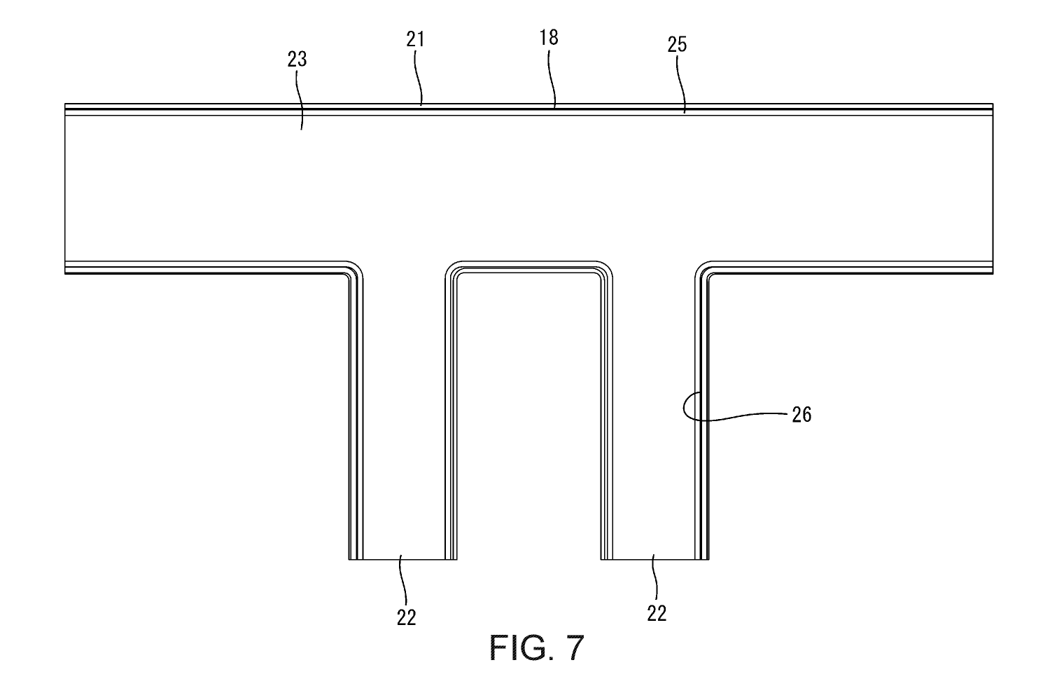

As shown in FIGS. 6 and 7, the divided surfaces 25 of the two divided members 23 and 24 are provided with protrusion-recess fitting portions 26 running over the entire lengths of the trunk line tube portion 21 and the branch line tube portions 22. The protrusion-recess fitting portions 26 are formed by cutting away one side, in the thickness direction, of each of the divided surfaces 25 of the divided members 23 and 24, so that the divided surface 25 has a recessed shape on that side and a protruding shape on the other side in the thickness direction. When putting the two divided members 23 and 24 together, as shown in FIGS. 4 and 5, the protruding shapes of the protrusion-recess fitting portions 26 of the divided member 23, which is one of the divided members, fit into the recessed shapes of the other divided member 24, and thus, the two divided members 23 and 24 are restrained from displacing from each other. Note that the two divided members 23 and 24 are formed to have the same shape and the same size.

Next, an example of a method for manufacturing the shielded conductive path 10 will be described.

During assembly, branch line electric wires 13 corresponding to a trunk line electric wire 12 for the optional device are connected to an intermediate section of that trunk line electric wire 12 in the length direction via a splice terminal 28 (see FIG. 9). The branch line electric wires 13 are connected in groups corresponding to the respective branch lines B, and thus, the branching portions 11 are formed at respective connecting sections (two sections, in the case shown in the drawings). Moreover, the opposite sides of the trunk line electric wires 12 in the length direction are covered by the trunk line shielding members 14 and 15, respectively. An end portion of each of the trunk line shielding members 14 and 15 that is located on the standard device side thereof is electrically connected to the vehicle body via a shielding shell, which is not shown, or the like.

Furthermore, the opposite sides of the trunk line electric wires 12 in the length direction are covered by the corrugated tubes 19 such that the corrugated tubes 19 enclose the outer circumference of the respective trunk line shielding members 14 and 15. Similarly, the branch line electric wires 13 (excluding portions near the branching portions 11) are covered by the branch line shielding members 16 and 17, and the branch line shielding members 16 and 17 are covered by the respective corrugated tubes 20. Then, connectors, which are not shown, are attached to opposite end portions of the trunk line M in its length direction and end portions of the branch lines B in their length directions.

After that, the relay connecting member 18 is assembled at an intermediate section (section corresponding to the branching portions 11) of the shielded conductive path 10 in the length direction so as to cover both of the two branching portions 11. During assembly, the trunk line electric wires 12 are placed in the divided member 23, which is one of the divided members, along a portion of the divided member 23 that constitutes the trunk line tube portion 21, and the branch line electric wires 13 are placed in the divided member 23 along portions of the divided member 23 that constitute the branch line tube portions 22. Then, the other divided member 24 is placed on the divided member 23 from above, the divided surfaces 25 of the two divided members 23 and 24 are aligned, and the two divided members 23 and 24 are put together in a state in which they are positioned relative to each other using the protrusion-recess fitting portions 26. Thus, the trunk line electric wires 12 are inserted in the trunk line tube portion 21, and the branch line electric wires 13 are inserted in the branch line tube portions 22, so that wiring routes of the trunk line M and the branch lines B are defined. Moreover, the branching portions 11 are concealed inside the relay connecting member 18, so that connecting sections of the splice terminals 28 are protected.

Subsequently, an open end portion of the trunk line shielding member 14 on the second side thereof in the length direction is expanded and placed over an end portion of the outer circumferential surface of the trunk line tube portion 21 on the first side thereof in the length direction. In this state, a band member 27 made of metal is externally attached to the open end portion of the trunk line shielding member 14 on the second side thereof in the length direction, and the trunk line shielding member 14 is fixed to the trunk line tube portion 21 using the fastening force of the band member 27 (see FIGS. 1 and 2). Similarly, an open end portion of the trunk line shielding member 15 on the first side thereof in the length direction is expanded and placed over an end portion of the outer circumferential surface of the trunk line tube portion 21 on the second side thereof in the length direction, a band member 27 is externally attached to the open end portion of the trunk line shielding member 15 on the first side thereof in the length direction, and the trunk line shielding member 15 is fixed to the trunk line tube portion 21.

Moreover, open end portions of the branch line shielding members 16 and 17 are expanded and placed over end portions (extending end portions) of outer circumferential surfaces of the respective branch line tube portions 22 in their length directions, band members 27 are externally attached to the open end portions of the respective branch line shielding members 16 and 17, and the branch line shielding members 16 and 17 are fixed to the respective branch line tube portions 22.

In this manner, the state in which the trunk line shielding members 14 and 15 are in contact with the outer circumferential surface of the trunk line tube portion 21 is secured, and also the state in which the branch line shielding members 16 and 17 are in contact with the outer circumferential surfaces of the respective branch line tube portions 22 is secured. Thus, a shielding structure extending over substantially the entire length of the shielded conductive path 10 is formed via the relay connecting member 18.

Moreover, as a result of the end portions of the trunk line tube portion 21 and the branch line tube portions 22 in their length directions being fixed using the band members 27, the two divided members 23 and 24 are kept in a closed state. After that, pieces of tape, which are not shown, are wrapped around end portions of the corrugated tubes 19 and 20 in their length directions and the relay connecting member 18, and the corrugated tubes 19 and 20 are thus held on the relay connecting member 18. At this time, the pieces of tape may be wrapped around the relay connecting member 18 to positions at which the pieces of tape cover the outer circumference of the respective band members 27.

As described above, according to Embodiment 1, the trunk line shielding members 14 and 15 and the branch line shielding members 16 and 17 are attached to and in contact with the relay connecting member 18 that is disposed corresponding to the branching portions 11, thereby forming a shielding structure. Thus, the branch structure of the branching portions 11 is realized by the relay connecting member 18, and it is no longer necessary to change the form of the trunk line shielding members 14 and 15 and the branch line shielding members 16 and 17 from an existing form. Consequently, adaptation to a branch structure of a relatively complex branching portion 11 is possible.

Moreover, the relay connecting member 18 has the trunk line tube portion 21 in which the trunk line electric wires 12 can be inserted and the branch line tube portions 22 in which the branch line electric wires 13 can be inserted, the trunk line shielding members 14 and 15 are attached to the outer circumferential surface of the trunk line tube portion 21, and the branch line shielding members 16 and 17 are attached to the outer circumferential surfaces of the respective branch line tube portions 22. Thus, the trunk line electric wires 12 and the branch line electric wires 13 can be protected by the relay connecting member 18, and the ease of attaching the trunk line shielding members 14 and 15 and the branch line shielding members 16 and 17 can be ensured.

Moreover, the branch line tube portions 22 and the trunk line tube portion 21 have an integrated shape in which the branch line tube portions 22 intersect and are connected to the trunk line tube portion 21 at the branching portions 11. Thus, the trunk line shielding members 14 and 15 and the branch line shielding members 16 and 17 can be connected to a single relay connecting member 18 together, and an increase in the number of components can be prevented. In addition, the angles (90 degrees, in the case shown in the drawings) at which the branch line tube portions 22 are connected to the trunk line tube portion 21 serve as the branching angles of the branching portions 11. Thus, the branching angles of the branching portions 11 can be accurately set, and the directions in which the branch lines B are drawn out can be guided.

Furthermore, the relay connecting member 18 is constituted by the pair of divided members 23 and 24 that can be separated from each other and put together with the trunk line electric wires 12 and the branch line electric wires 13 held therebetween. Thus, the operation of attaching the relay connecting member 18 can be performed after the branch line electric wires 13 have been connected to the trunk line electric wires 12, and thus the workability of the attachment operation is excellent.

### Embodiment 2

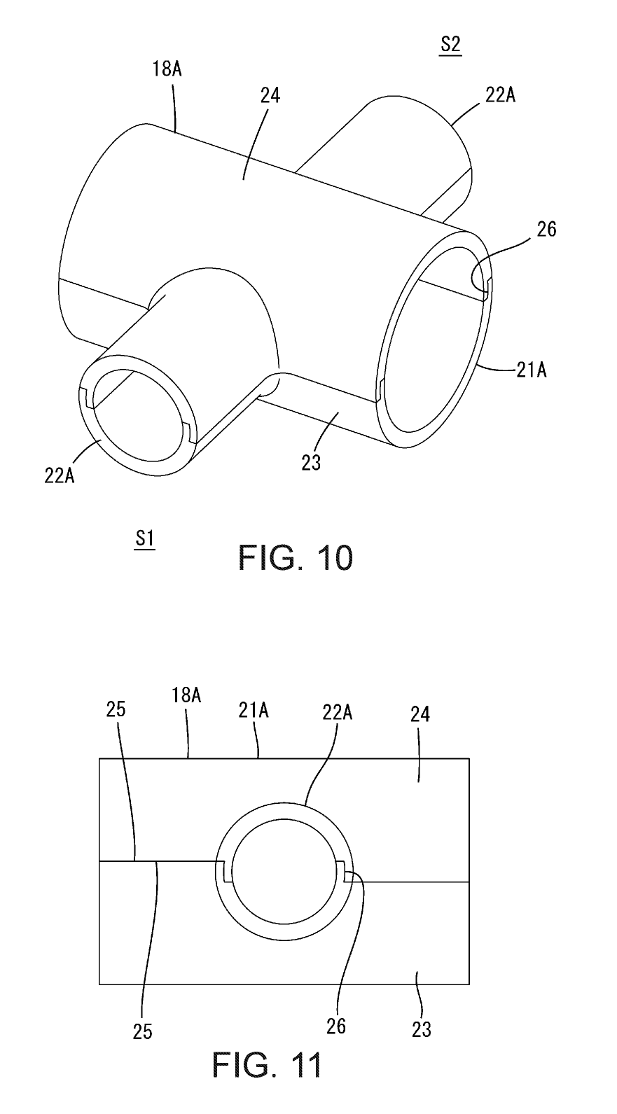

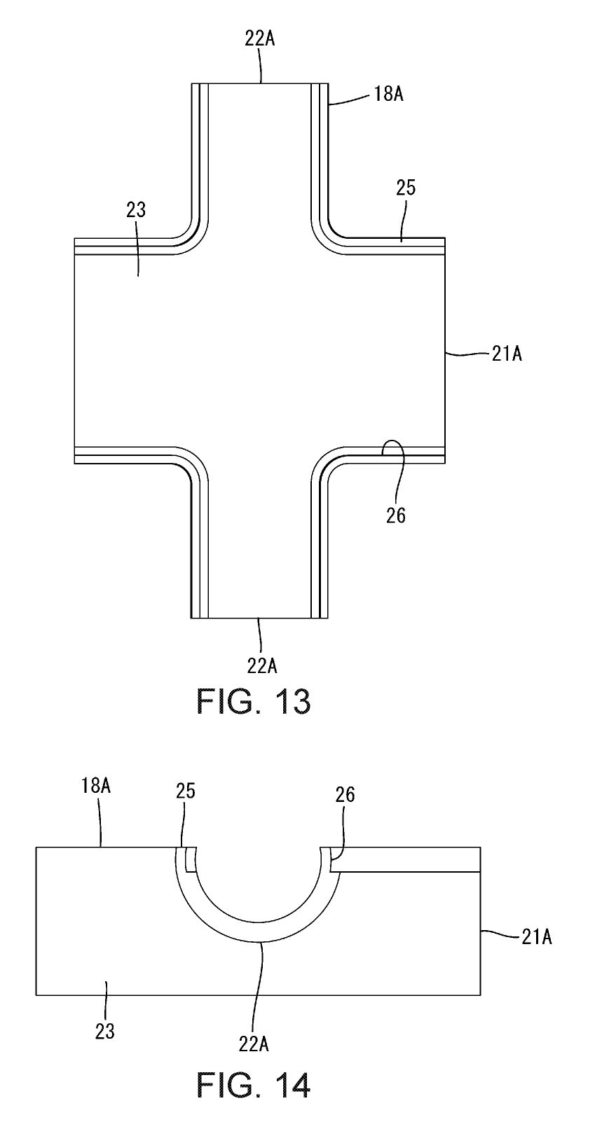

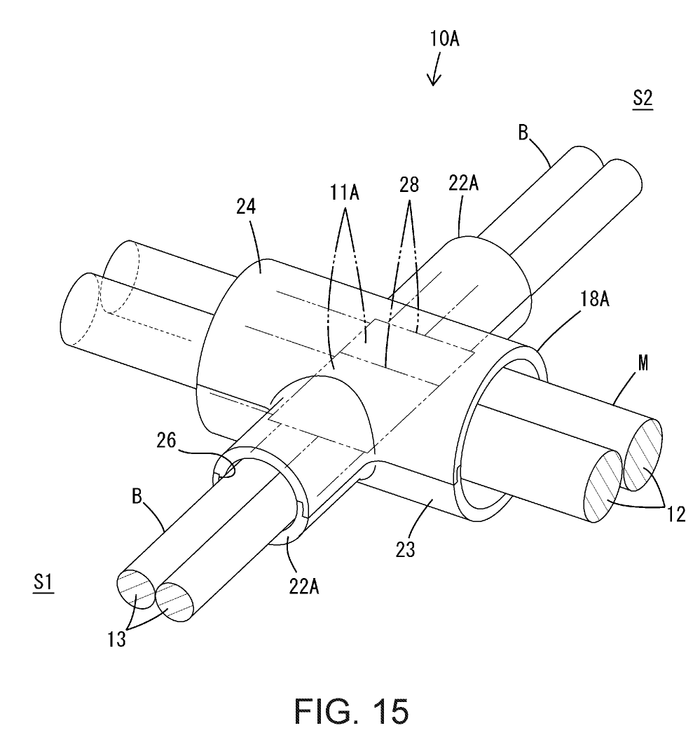

FIGS. 10 to 15 show Embodiment 2. FIG. 15 shows the trunk line electric wires 12, the branch line electric wires 13, and a relay connecting member 18A, of a shielded conductive path 10A. Note that the trunk line shielding members 14 and 15 and the branch line shielding members 16 and 17 are omitted from this drawing. Embodiment 2 differs from Embodiment 1 in terms of the branch structure of branching portions 11A and the structure of the relay connecting member 18A adapted to the branch structure, but is otherwise, including the assembly steps, the same as Embodiment 1. Accordingly, components that are the same as or correspond to those of Embodiment 1 are denoted by the same reference numerals, and descriptions overlapping those in Embodiment 1 are omitted unless necessary.

As shown in FIG. 15, the branch lines B constitute two paths that intersect (more specifically, orthogonally intersect) the trunk line M at an intermediate section of the trunk line M in the length direction and that extend from the trunk line M toward the respective spaces S1 and S2 on opposite sides of the trunk line M. Thus, the branch line electric wires 13 extend from the branching portions 11A in opposite directions toward the spaces S1 and S2 on opposite sides. As is the case with Embodiment 1, at the branching portions 11A, the branch line electric wires 13 are connected to the corresponding trunk line electric wires 12 via the splice terminals 28.

As shown in FIGS. 10 and 11, as is the case with Embodiment 1, the relay connecting member 18A is constituted by a cylindrical tubular, trunk line tube portion 21A extending along the length direction of the trunk line M and cylindrical tubular, branch line tube portions 22A extending along the length directions of the respective branch lines B. The branch line tube portions 22A are slightly smaller than the trunk line tube portion 21A. The branch line tube portions 22A are integrally connected to an intermediate portion of the trunk line tube portion 21A in the length direction, and are provided as a pair so as to protrude in opposite directions toward the respective spaces 81 and S2 on opposite sides of the trunk line tube portion 21A. Thus, the relay connecting member 18A is formed in a substantially cross shape as a whole, and is configured such that its center portion is located corresponding to the branching portions 11A.

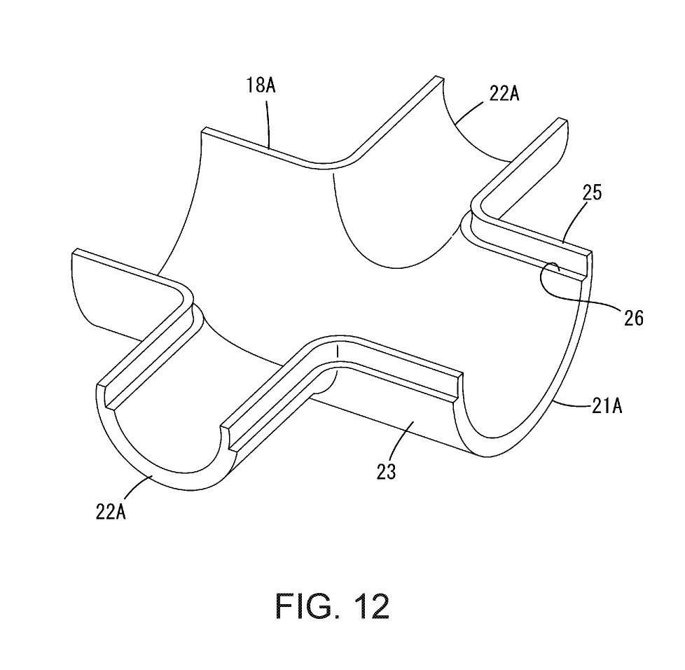

The relay connecting member 18A is constituted by a pair of divided members 23 and 24 that can be separated from each other and put together, and the divided surfaces 25 of the two divided members 23 and 24 are provided with the protrusion-recess fitting portions 26. In these respects, Embodiment 2 is the same as Embodiment 1 (see FIGS. 12 to 14). Here, the two divided members 23 and 24 are formed to have the same shape and the same size.

In the case of Embodiment 2, the trunk line electric wires 12 are drawn out from the opposite end portions of the trunk line tube portion 21A in its length direction, and the branch line electric wires 13 are drawn out from the end portions of the corresponding branch line tube portions 22A in their length directions. Thus, the shielded conductive path 10A is formed extending in a cross shape. Therefore, when the relay connecting member 18A of the Embodiment 2 is used, adaptation to a case in which optional devices corresponding to the respective branch lines B are located spaced away from each other on opposite sides (in spaces S1 and S2) of the trunk line M is also possible.

### OTHER EMBODIMENTS

Hereinafter, other embodiments will be briefly described.

(1) The trunk line electric wires and the branch line electric wires may be connected at the branching portions through soldering or the like. Moreover, a portion of each trunk line electric wire may be directly continuous with and extend as a branch line electric wire through a branching portion.

(2) The trunk line shielding members and the branch line shielding members may be obtained by forming pliable metal foil into a tubular shape.

(3) It is sufficient that the relay connecting member is formed to have a structure adapted to the branch structure of a branching portion. For example, the relay connecting member may have a structure in which a plurality of branch line tube portions are alternatingly arranged on opposite sides of a trunk line tube portion in accordance with the branch structure of branching portions.

(4) The trunk line tube portion and the branch line tube portions may have a cylindrical tubular shape with an elliptical or oval cross section, or may have a rectangular tubular shape (including a box-like shape) instead of a circular tubular shape.

(5) A trunk line tube portion and a branch line tube portion may be separate bodies that can be separated from each other. Moreover, a plurality of branch line tube portions may also be separate bodies that can be separated from each other.

(6) Substantially the entire outer circumferential surface of the relay connecting member may be covered by the trunk line shielding members and the branch line shielding members. In this case, the relay connecting member is not necessarily required to have a tubular shape that encloses the trunk line electric wires and the branch line electric wires, and may have any shape.

(7) The band members may be made of a synthetic resin.

(8) Depending on the optional specification, a configuration may be conceivable in which a branch line is not inserted in a branch line tube portion.

### LIST OF REFERENCE NUMERALS

10, 10A: Shielded Conductive Path
11, 11A: Branching Portion
12: Trunk Line Electric Wire
13: Branch Line Electric Wire
14, 15: Trunk Line Shielding Member
16, 17: Branch Line Shielding Member
18, 18A: Relay Connecting Member
21, 21A: Trunk Line Tube Portion
22, 22a: Branch Line Tube Portion
23, 24: Divided Member

What is claimed is:

1. A shielded conductive path comprising:
a trunk line electric wire;
a branch line electric wire connected to the trunk line electric wire via a branching portion;
a trunk line shielding member having electrical conductivity and enclosing an outer circumference of the trunk line electric wire;
a branch line shielding member having electrical conductivity and enclosing an outer circumference of the branch line electric wire; and
a relay connecting member having electrical conductivity and disposed corresponding to the branching portion, the trunk line shielding member and the branch line shielding member being attached to and in contact with the relay connecting member.

2. The shielded conductive path according to claim 1,
wherein the relay connecting member has a trunk line tube portion in which the trunk line electric wire can be inserted and a branch line tube portion in which the branch line electric wire can be inserted, the trunk line shielding member is attached to an outer circumferential surface of the trunk line tube portion, and the branch line shielding member is attached to an outer circumferential surface of the branch line tube portion.

3. The shielded conductive path according to claim 2,
wherein the branch line tube portion and the trunk line tube portion have an integrated shape in which the branch line tube portion and the trunk line tube portion intersect and are connected to each other at the branching portion.

4. The shielded conductive path according to claim 2,
wherein the relay connecting member is constituted by a pair of divided members that can be separated from each other lengthwise and put together with the trunk line electric wire and the branch line electric wire held between the divided members.

5. A relay connecting member used for the shielded conductive path according to claim 1.
